(19) United States
(12) Patent Application Publication
(10) Pub. No.: US 2004/0245615 A1
(43) Pub. Date: Dec. 9, 2004

(54) Point to point memory expansion system and method

(75) Inventors: James W. Cady, Austin, TX (US); Russell Rapport, Austin, TX (US); Julian Partridge, Austin, TX (US); James Douglas Wehrly JR., Austin, TX (US); James Wilder, Austin, TX (US); David L. Roper, Austin, TX (US); Jeff Buchle, Austin, TX (US)

Correspondence Address: J. Scott Denko, Andrews & Kurth, L.L.P., Suite 1700, 111 Congress Ave., Austin, TX, 78701, US

(73) Assignee: Staktek Group, L.P.

(21) Appl. No.: 10/624,097

(22) Filed: Jul. 21, 2003

Related U.S. Application Data
(63) Continuation-in-part of application No. 10/453,398, filed on Jun. 3, 2003.

(51) Int. Cl. H01L 23/538

(52) U.S. Cl. 257/686

(57) ABSTRACT

With the use of stacked modules, a system and method for point to point addressing of multiple integrated memory circuits is provided. A single memory expansion board is populated with stacked modules of integrated circuits. The single memory expansion board is located at the terminus of a transmission line, thus, effectively placing at a relative single point in the addressing system, added memory capacity that would otherwise have required multiple memory expansion boards and, consequently, a longer bus. Therefore, signal degradation issues are mitigated and the system has improved tolerance for higher signal speeds with added memory capacity. In a preferred embodiment, a four DIMM socket memory access bus that does not employ stacking is replaced with a single DIMM socket bus that supports stacking up to four high on a single DIMM. Although the present invention is preferably employed to advantage using stacked modules comprised from multiple CSPs, it may be employed with modules comprised from any number and type of integrated circuits including any type of packaging, whether CSP or leaded.

### TECHNICAL FIELD

The present invention relates to accessing memory circuits and, in particular, to accessing memory circuits aggregated in stacks.

### BACKGROUND OF THE INVENTION

In general, when an electrical interconnect is less than half the spatial extent of the leading edge of a signal, that interconnect is better modeled as a lumped element rather than a transmission line. As bus signal speeds increase, however, understanding memory signal performance becomes a complex analysis. For example, the bus connecting a memory expansion board to a system is typically a transmission line with periodic discontinuities that adversely affect impedance, wave velocity, and bandwidth and cutoff frequency. Further, as bus signal speeds rise from the 100 MHz of the PC-100 bus to the 200 MHz and 333 MHz speeds of the DDR2 bus, such deleterious effects increase. Newer microprocessors are now being described as utilizing 800 MHz bus speeds.

As speeds increase, memory expansion becomes more difficult. Signal deficiencies become more pronounced as bus speeds rise, making multiple stubs more problematic and thus inhibiting the tendency to add memory by adding DIMMs. For example, the PC-100 bus allows four DIMM sockets on a bus. As bus signal speeds increase, however, the long bus lengths caused by multiple DIMMs become unacceptable while magnifying bandwidth cutoff frequency, capitance, and DIMM socket skew problems.

There are methods to reduce the described deleterious effects. For example, a lower signal voltage swing will allow a smaller driver and result in reduced capacitance-related drops. Other techniques change memory board design. For example, series stub terminated logic, “SSTL-2,” uses series resistors to isolate the stub from the line thus reducing ringing with reduced power. SSTL-2 has been standardized within JEDEC and is typically used with DDR, for example. There is also a direct RAMBUS current mode version of bus design that avoids much of the wired-OR glitch.

However, these methods typically do not directly address the fundamental that as bus speeds increase, signal behavior degrades to an unacceptable level at shorter and shorter distances from the driver. What is needed, therefore, is a new system and method for increasing integrated circuit memory capacity that mitigates the adverse effects arising from faster bus speeds that would otherwise arise with such increased memory capacity.

### SUMMARY OF THE INVENTION

With the use of stacked modules, a system and method for point to point addressing of multiple integrated memory circuits is provided. A single memory expansion board is populated with stacked modules of integrated circuits. The single memory expansion board is located at a memory site at the terminus of a transmission line, thus, effectively placing at a relative single point in the addressing system, added memory capacity that would otherwise have required multiple memory expansion boards and, consequently, a longer bus with multiple discontinuities. Preferred termination techniques such as source termination, end termination, and combinations of these two techniques may be used on the point-to-point data lines, therefore, signal degradation issues are mitigated and the system has improved tolerance for higher signal speeds. In a preferred embodiment, a four DIMM socket memory access bus that does not employ stacking is replaced with a single DIMM socket bus that supports stacking up to four high on a single DIMM.

Although the present invention is preferably employed to advantage using stacked modules comprised from multiple CSPs, it may be employed with modules comprised from any number and type of integrated circuits including any type of packaging, whether CSP or leaded.

### SUMMARY OF THE DRAWINGS

FIG. 1 is an elevation view of a high-density circuit module devised for use in a preferred embodiment of the present invention.

FIG. 2 is an elevation view of a stacked high-density circuit module devised for use in a preferred embodiment of the present invention.

FIG. 3 depicts, in enlarged view, the area marked “A” in FIG. 2 in a stacked module that may be employed to advantage in the present invention.

FIG. 4 depicts, in enlarged view, one alternative construction for of the area marked “A” in FIG. 2.

FIG. 5 depicts in enlarged view, the area marked “B” in FIG. 2 in a stacked module that may be employed to advantage in the present invention.

FIG. 6 depicts, in enlarged view, a portion of a flex circuitry employed with the structure of FIG. 4 in an alternative construction for a module that may be employed in the present invention.

FIG. 7 is an elevation view of a portion of an alternative construction step in construction of an alternative module for use in the present invention.

FIG. 8 is a depiction of a memory access system in accordance with a preferred embodiment of the present invention.

### DESCRIPTION OF PREFERRED EMBODIMENTS

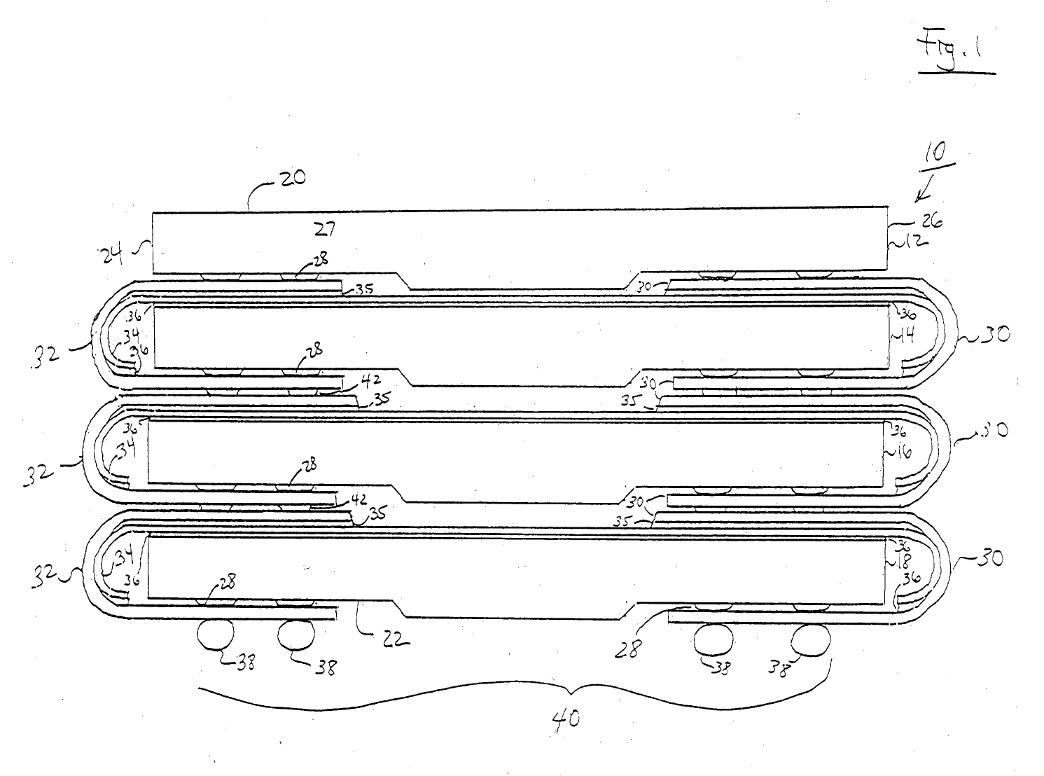

FIG. 1 is an elevation view of an example module 10 that may be employed in accordance with a preferred embodiment of the present invention. Exemplar module 10 is comprised of four CSPs: level four CSP 12, level three CSP 14, level two CSP 16, and level one CSP 18. Each of the depicted CSPs has an upper surface 20 and a lower surface 22 and opposite lateral sides or edges 24 and 26 and include at least one integrated circuit surrounded by a body 27.

The invention is used with modules 10 that may be comprised from CSP or leaded packages of a variety of types and configurations. For example, modules 10 may also be comprised from CSPs that are die-sized, as well those that are near chip-scale as well as the variety of ball grid array packages known in the art including those that exhibit bare die connectives on one major surface. Thus, the term CSP should be broadly considered in the context of this application. The invention may be used with modules 10 that use any of the CSP configurations available in the art where an array of connective elements is available from at least one major surface as well as with modules 10 comprised from leaded packages, and where space permits, with stacked modules comprised from leaded packages.

Shown in FIG. 1 are low profile contacts 28 along lower surfaces 22 of the illustrated constituent CSPs 12, 14, 16, and 18. Low profile contacts 28 provide connection to the integrated circuit or circuits within the respective packages.

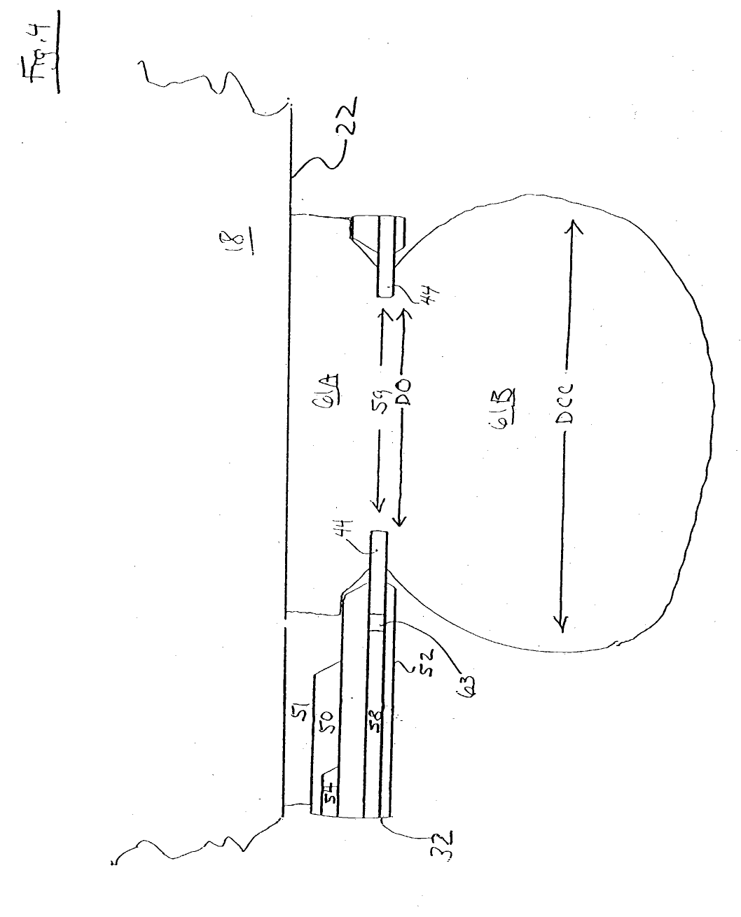

CSPs often exhibit an array of balls along lower surface 22. Such ball contacts are typically solder ball-like structures appended to contact pads arrayed along lower surface 22. In some modules 10 employed with the present invention, CSPs that exhibit balls along lower surface 22 are processed to strip the balls from lower surface 22 or, alternatively, CSPs that do not have ball contacts or other contacts of appreciable height are employed. Only as a further example of the variety of contacts that may be employed in alternative modules employed in preferred embodiments of the present invention, a module 10 is later disclosed in FIG. 4 and the accompanying text that is constructed using a CSP that exhibits ball contacts along lower surface 22. The ball contacts are then reflowed to create what will be called a consolidated contact.

Modules 10 may also be devised that employ both standard ball contacts and low profile contacts or consolidated contacts. For example, in the place of low profile inter-flex contacts 42 or, in the place of low profile contacts 28, or in various combinations of those structures, standard ball contacts may be employed at some levels of module 10, while low profile contacts and/or low profile inter-flex contacts or consolidated contacts are used at other levels.

A typical eutectic ball found on a typical CSP memory device is approximately 15 mils in height. After solder reflow, such a ball contact will typically have a height of about 10 mils. In modules 10 used in preferred modes of the present invention, low profile contacts 28 and/or low profile inter-flex contacts 42 have a height of approximately 7 mils or less and, more preferably, less than 5 mils.

Where present, the contact sites of a CSP that are typically found under or within the ball contacts typically provided on a CSP, participate in the creation of low profile contacts 28. One set of methods by which high-temperature types of low profile contacts 28 suitable for use in embodiments of the present invention are created is disclosed in co-pending U.S. patent application Ser. No. 10/457,608, filed Jun. 9, 2003 which has been incorporated by reference. In other embodiments, more typical solders, in paste form, for example, may be applied either to the exposed contact sites or pads along lower surface 22 of a CSP and/or to the appropriate flex contact sites of the designated flex circuit to be employed with that CSP.

In FIG. 1, iterations of flex circuits (“flex”, “flex circuits,” “flexible circuit structures,” “flexible circuitry,” “flex circuitry”) 30 and 32 are shown connecting various constituent CSPs. Any flexible or conformable substrate with an internal layer connectivity capability may be used as a preferable flex circuit in the invention. The entire flex circuit may be flexible or, as those of skill in the art will recognize, a PCB structure made flexible in certain areas to allow conformability around CSPs and rigid in other areas for planarity along CSP surfaces may be employed as an alternative flex circuit in modules 10. For example, structures known as rigid-flex may be employed.

Form standard 34 is shown disposed adjacent to upper surface 20 of each of the CSPs below level four CSP 12. Form standard 34 may be fixed to upper surface 20 of the respective CSP with an adhesive 36 which preferably is thermally conductive. Form standard 34 may also, in alternative embodiments, merely lay on 10 upper surface 20 or be separated from upper surface 20 by an air gap or medium such as a thermal slug or non-thermal layer.

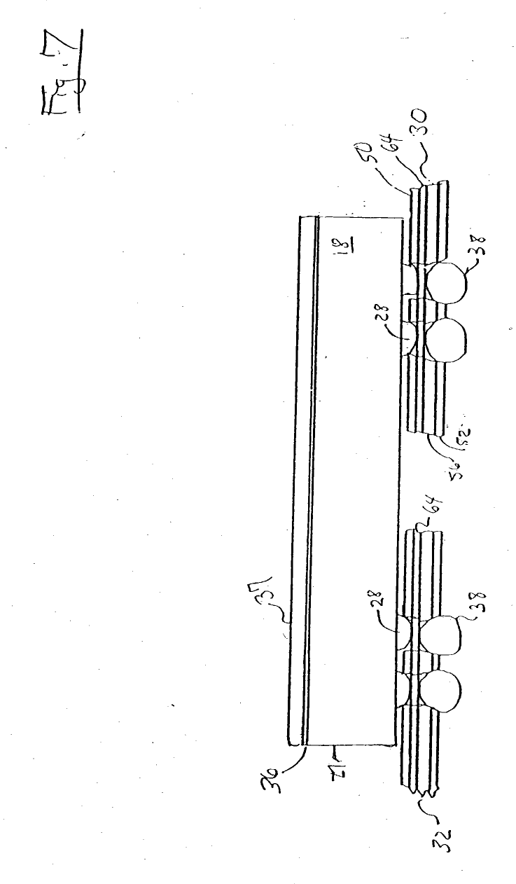

In other modules 10 employed with the present invention, a heat spreader may act as a heat transference media and reside between the flex circuitry and the package body 27 or may be used in place of form standard 34. Such a heat spreader is shown in FIG. 7 as an example and is identified by reference numeral 37. In still other embodiments, there will be no heat spreader 37 or form standard 34 and the embodiment may use the flex circuitry as a heat transference material.

With continuing reference to FIG. 1, form standard 34 is devised from copper to create, as shown in FIG. 1, a mandrel that mitigates thermal accumulation 20 while providing a standard-sized form about which flex circuitry is disposed. Form standard 34 may take other shapes and forms such as, for example, an angular “cap” that rests upon the respective CSP body. Form standard 34 also need not be thermally enhancing although such attributes are preferable. The form standard 34 allows modules 10 to be devised with CSPs of varying sizes, while articulating a single set of connective structures useable with the varying sizes of CSPs. Thus, a single set of connective structures such as flex circuits 30 and 32 (or a single flexible circuit in the mode where a single flex is used in place of the flex circuit pair 30 and 32) may be devised and used with the form standard 34 method and/or systems disclosed herein to create stacked modules from CSPs having different sized packages. This will allow the same flexible circuitry set design to be employed to create iterations of a stacked module 10 from constituent CSPs having a first arbitrary dimension X across attribute Y (where Y may be, for example, package width), as well as modules 10 from constituent CSPs having a second arbitrary dimension X prime across that same attribute Y. Thus, CSPs of different sizes may be stacked into modules 10 with the same set of connective structures (i.e. flex circuitry). Preferably, form standard 34 will present a lateral extent broader than the upper major surface of the CSP over which it is disposed. Thus, the CSPs from one manufacturer may be aggregated into a stacked module 10 with the same flex circuitry used to aggregate CSPs from another manufacturer into a different stacked module 10 despite the CSPs from the two different manufacturers having different dimensions.

Further, as those of skill will recognize, mixed sizes of CSPs may be implemented into the same module 10, such as would be useful to implement embodiments of a system-on-a-stack such as those disclosed in co-pending application U.S. patent application Ser. No. 10/136,890, filed May 2, 2002, which is hereby incorporated by reference and commonly owned by the assignee of the present application.

Preferably, portions of flex circuits 30 and 32 are fixed to form standard 34 by adhesive 35 which is preferably a tape adhesive, but may be a liquid adhesive or may be placed in discrete locations across the package. Preferably, adhesive 35 is thermally conductive.

Preferably, flex circuits 30 and 32 are multi-layer flexible circuit structures that have at least two conductive layers examples of which are those described in U.S. application Ser. No. 10/005,581, now U.S. Pat. No. 6,576,992, which has been incorporated by reference herein. Other modules 10 used in preferred embodiments may, however, employ flex circuitry, either as one circuit or two flex circuits to connect a pair of CSPs, that have only a single conductive layer.

Preferably, the conductive layers employed in flex circuitry of module 10 are metal such as alloy 110. The use of plural conductive layers provides advantages and the creation of a distributed capacitance across module 10 intended to reduce noise or bounce effects that can, particularly at higher frequencies, degrade signal integrity, as those of skill in the art will recognize.

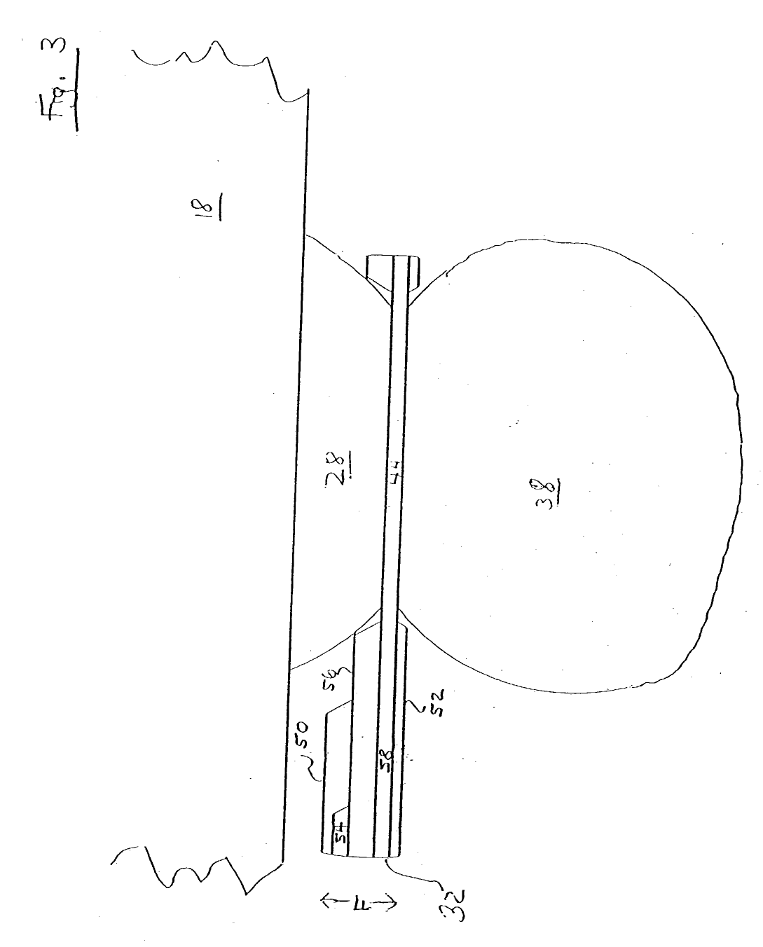

Module 10 of FIG. 1 has plural module contacts 38 collectively identified as module array 40. Connections between flex circuits are shown as being implemented with low profile inter-flex contacts 42 which are, preferably, low profile contacts comprised of solder-combined with pads and/or rings such as the flex contacts 44 shown in FIG. 3 or flex contacts 44 with orifices as shown in FIG. 4 being just examples.

Form standard 34, as employed in one type of module 10 employed in a preferred embodiment, is approximately 5 mils in thickness, while flex circuits 30 and 32 are typically thinner than 5 mils. Thus, the depiction of FIG. 1 is not to scale.

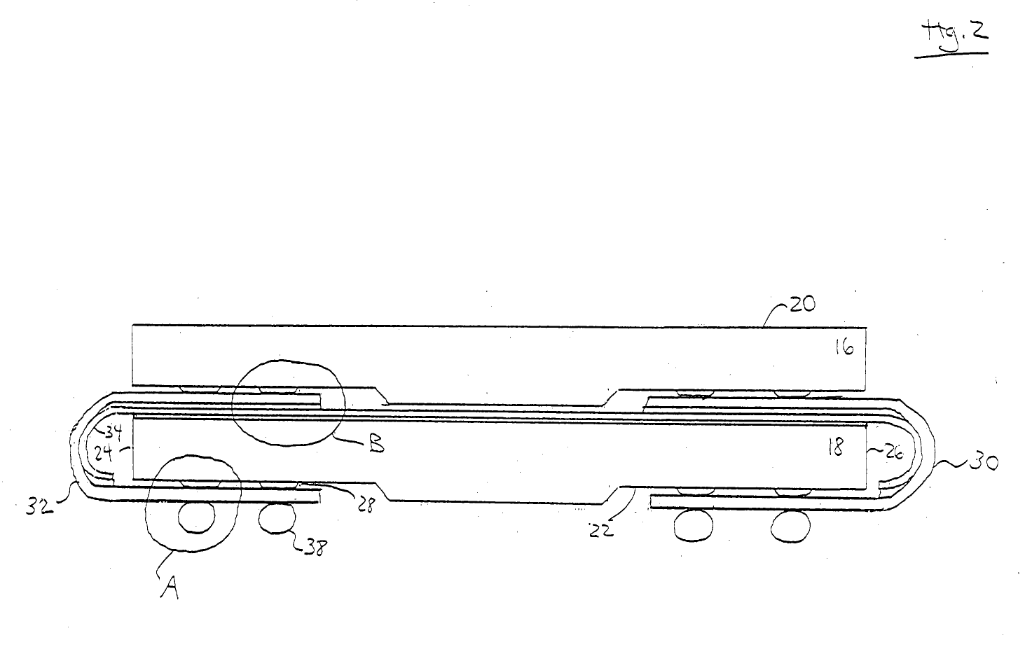

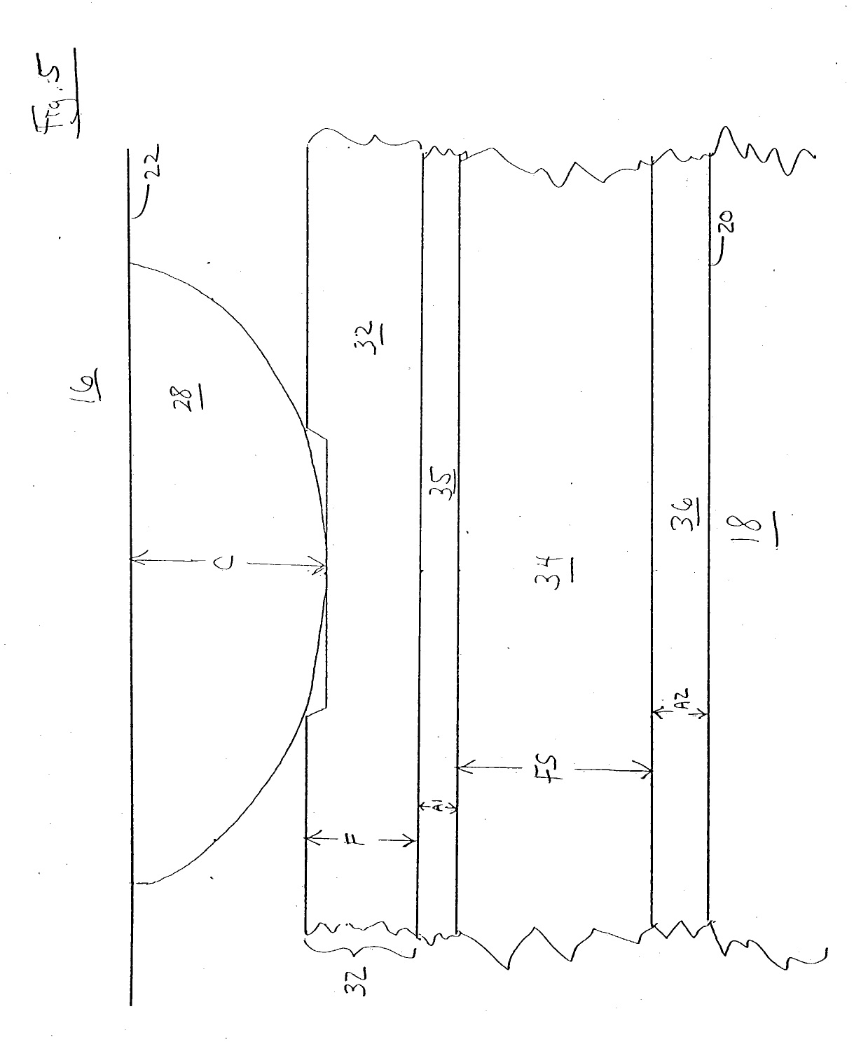

FIG. 2 illustrates an exemplar two-high module 10 that may be employed in accordance with an alternative embodiment of the present invention. The depiction of FIG. 2 identifies two areas “A” and “B”, respectively, that are shown in greater detail in later figures. In later FIGS. 3 and 4, there are shown details of two of the many alternatives for the area marked “A” in FIG. 2. It should be understood that many different connection alternatives are available for the modules 10 used in the present invention. FIG. 5 depicts details of the area marked “B” in FIG. 2.

FIG. 3 depicts, in enlarged view, one alternative for structures that may be used in the area marked “A” in FIG. 2. FIG. 3 depicts an example preferred connection between an example low profile contact 28 and module contact 38 through flex contact 44 of flex 32 to illustrate a solid metal path from level one CSP 18 to module contact 38 and, therefore, to an application PWB or memory expansion board to which module 10 is connectable.

Flex 32 is shown in FIG. 3 to be comprised of multiple conductive layers. This is merely an exemplar flexible circuitry that may be employed with some modules 10 employable in the present invention. A single conductive layer and other variations on the flexible circuitry may, as those of skill will recognize, be employed to advantage in other modules 10 employed in the present invention.

Flex 32 has a first outer surface 50 and a second outer surface 52. Preferred flex circuit 32 has at least two conductive layers interior to first and second outer surfaces 50 and 52. There may be more than two conductive layers in flex 30 and flex 32 and other types of flex circuitry may employ only one conductive layer. In the depicted module 10, first conductive layer 54 and second conductive layer 58 are interior to first and second outer surfaces 50 and 52. Intermediate layer 56 lies between first conductive layer 54 and second conductive layer 58. There may be more than one intermediate layer, but one intermediate layer of polyimide is preferred. The designation “F” as shown in FIG. 3 notes the thickness “F” of flex circuit 32 which, preferably, is approximately 3 mils. Thinner flex circuits may be employed, particularly where only one conductive layer is employed, and flex circuits thicker than 3 mils may also be employed, with commensurate addition to the overall height of module 10.

As depicted in FIG. 3 and seen in more detail in Figs. found in U.S. application Ser. No. 10/005,581, now U.S. Pat. No. 6,576,992, which has been incorporated by reference, an example flex contact 44 is comprised from metal at the level of second conductive layer 58 interior to second outer surface 52.

FIG. 4 depicts an alternative structure for the connection in the area marked “A” in FIG. 2. In the depiction of FIG. 4, a flex contact 44 is penetrated by orifice 59 which has a median opening of dimension “DO” indicated by the arrow in FIG. 4. Demarcation gap 63 is shown in FIG. 4. This gap which is further described in incorporated U.S. patent application Ser. No. 10/005,581, now U.S. Pat. No. 6,576,992, may be employed to separate or demarcate flex contacts such as flex contact 44 from its respective conductive layer. Also shown in FIG. 4 is an optional adhesive or conformed material 51 between flex circuit 32 and CSP 18.

The consolidated contact 61 shown in FIG. 4 provides connection to CSP 18 and passes through orifice 59. Consolidated contact 61 may be understood to have two portions 61A that may be identified as an “inner” flex portion and, 61B that may be identified as an “outer” flex portion, the inner and outer flex portions of consolidated contact 61 being delineated by the orifice. The outer flex portion 61 B of consolidated contact 61 has a median lateral extent identified in FIG. 4 as “DCC” which is greater than the median opening “DO” of orifice 59. The depicted consolidated contact 61 is preferably created by providing a CSP with ball contacts. Those ball contacts are placed adjacent to flex contacts 44 that have orifices 59. Heat sufficient to melt the ball contacts is applied. This causes the ball contacts to melt and reflow in part through the respective orifices 59 to create emergent from the orifices, outer flex portion 61B, leaving inner flex portion 61A nearer to lower surface 22 of CSP 18.

Thus, the depicted module 10 is constructed with a level one CSP 18 that exhibits balls as contacts, but those ball contacts are re-melted during the construction of module 10 to allow the solder constituting the ball to pass through orifice 59 of the respective flex contact 44 to create a consolidated contact 61 that serves to connect CSP 18 and flex circuitry 32, yet preserve a low profile aspect to module 10 while providing a contact for module 10. Those of skill will recognize that this alternative connection strategy may be employed with any one or more of the CSPs when CSPs are used in module 10.

As those skilled will note, a consolidated contact 61 may be employed to take the place of a low profile contact 28 and module contact 38. Further, either alternatively, or in addition, a consolidated contact 61 may also be employed in the place of a low profile contact 28 and/or an inter-flex contact 42 in alternatives where the conductive layer design of the flex circuitry will allow the penetration of the flex circuitry implicated by the strategy.

FIG. 5 depicts the area marked “B” in FIG. 2. The depiction of FIG. 5 includes approximations of certain dimensions of several elements in a preferable module 10. It must be understood that these are just examples relevant to a few designs for modules 10 that may be employed to advantage in the present invention, and those of skill will immediately recognize that the invention may be implemented with any design for module 10 that includes sufficient memory capacity for the application.

There are a variety of methods of creating low profile contacts 28 when used in creating module 10. One method that is effective is the screen application of solder paste to the exposed CSP contact pad areas of the CSP and/or to the contact sites of the flex circuitry. For screened solder paste, the reflowed joint height of contact 28 will typically be between 0.002″ and 0.006″ (2 to 6 mils). The stencil design, the amount of solder remaining on ‘ball-removed’ CSPs, and flex planarity will be factors that could have a significant effect on this value. Low profile contact 28 has a height “C” which, preferably, is between 2 and 7 mils. Flex circuitry 32, with one or two or more conductive layers, has a thickness “F” of about 4 mils or less, preferably, when flex circuitry is employed in a module 10 employed in the invention. Adhesive layer 35 has a preferred thickness “A1” of between 1 and 1.5 mils. Form standard 34 has a preferred thickness “FS” of between 4 and 6 mils and, adhesive layer 36 has a thickness “A2” of between 1 and 2 mils. Thus, for one exemplar type of module 10 that may be employed in the present invention, the total distance between lower surface 22 of CSP 16 and upper surface 20 of CSP 18 passing through one of low profile contacts 28 of CSP 16 is approximated by the formula:

(C+F+A1+FS+A2)—distance low profile contact 28 penetrates into flex 32. (1)

In practice, this should be approximately between 9 and 20 mils in a preferred construction for module 10. A similar calculation can be applied to identify the preferred distances between, for example, CSP 14 and CSP 16 in a four-high module 10 that employs CSPs. In such cases, the height of inter-flex contact 42 and thickness of another layer of flex circuit 32 will be added to the sum to result in a preferred range of between 13 and 31 mils. It should be noted that in some modules 10, not all of these elements will be present, and in others, added elements will be found and it should be remembered that modules 10 may be employed in the present invention that employ integrated circuits in leaded packages.

Further, for example, some of the adhesives may be deleted, and form standard 34 may be replaced or added to with a heat spreader 37 and, in still other versions, neither a form standard 34 nor a heat spreader 37 will be found. As an example, where there is no use of a heat spreader 37 or form standard 34, the distance between lower surface 22 of CSP 16 and upper surface 20 of CSP 18 in a two-element module 10 will be preferably between 4.5 and 12.5 mils and more preferably less than 11 mils.

It is often desirable, but not required, to create low profile contacts 28 and low profile inter-flex contacts 42 using HT joints as described in co-pending application U.S. patent application Ser. No. 10/457,608 which has been incorporated by reference herein.

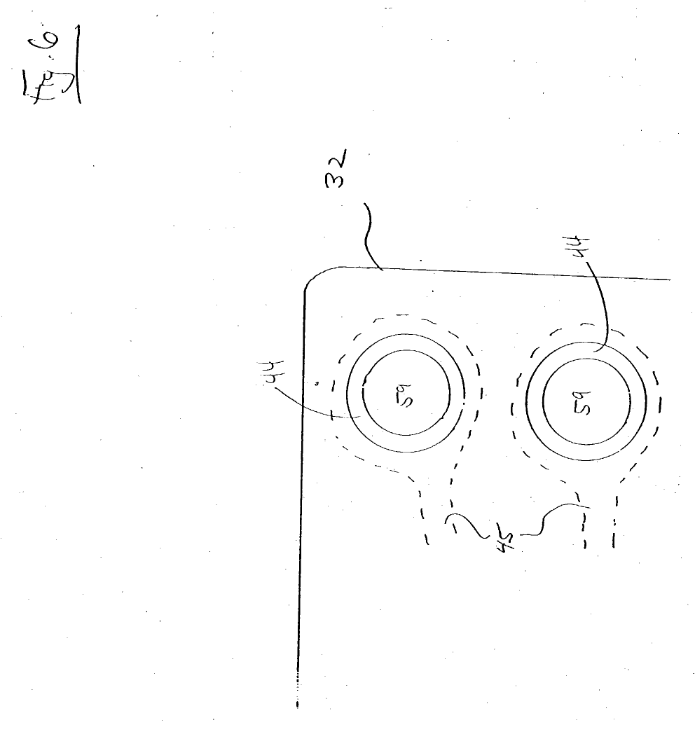

FIG. 6 depicts a plan view of a contact structure in flex 32 that may be employed to implement the consolidated contact 61 shown earlier in FIG. 4. Shown in FIG. 6 are two exemplar flex contacts 44 that each have an orifice 59. It may be considered that flex contacts 44 extend further than the part visible in this view as represented by the dotted lines that extend into traces 45. The part of flex contact 44 visible in this view is to be understood as being seen through windows in other layers of flex 32 as described in the incorporated by reference application U.S. patent application Ser. No. 10/005,581, now U.S. Pat. No. 6,576,992, depending upon whether the flex contact is articulated at a first conductive layer or, if it is present in flex 32, a second conductive layer and intermediate layer and whether the flex contact is for connection to the lower one of two CSPs or the upper one of two CSPs in a module 10.

FIG. 7 depicts a flexible circuit connective set of flex circuits 30 and 32 that has a single conductive layer 64. It should be understood with reference to FIG. 6, that flex circuits 30 and 32 extend laterally further than shown and have portions which are, in the construction of module 10, brought about and disposed above the present, heat spreader 37, a form standard 34 (not shown), and/or upper surface 20 of CSP 18. In this single conductive layer flex embodiment of module 10, there are shown first and second outer layers 50 and 52 and intermediate layer 56.

Heat spreader 37 is shown attached to the body 27 of first level CSP 18 through adhesive 36. In some embodiments, a heat spreader 37 or a form standard 34 may also be positioned to directly contact body 27 of the respective CSP.

Heat transference from module can be improved with use of a form standard 34 or a heat spreader 37 comprised of heat transference material such as a metal and preferably, copper or a copper compound or alloy, to provide a significant sink for thermal energy. Although the flex circuitry operates as a heat transference material, such thermal enhancement of module 10 particularly presents opportunities for improvement of thermal performance where larger numbers of CSPs are aggregated in a single stacked module 10.

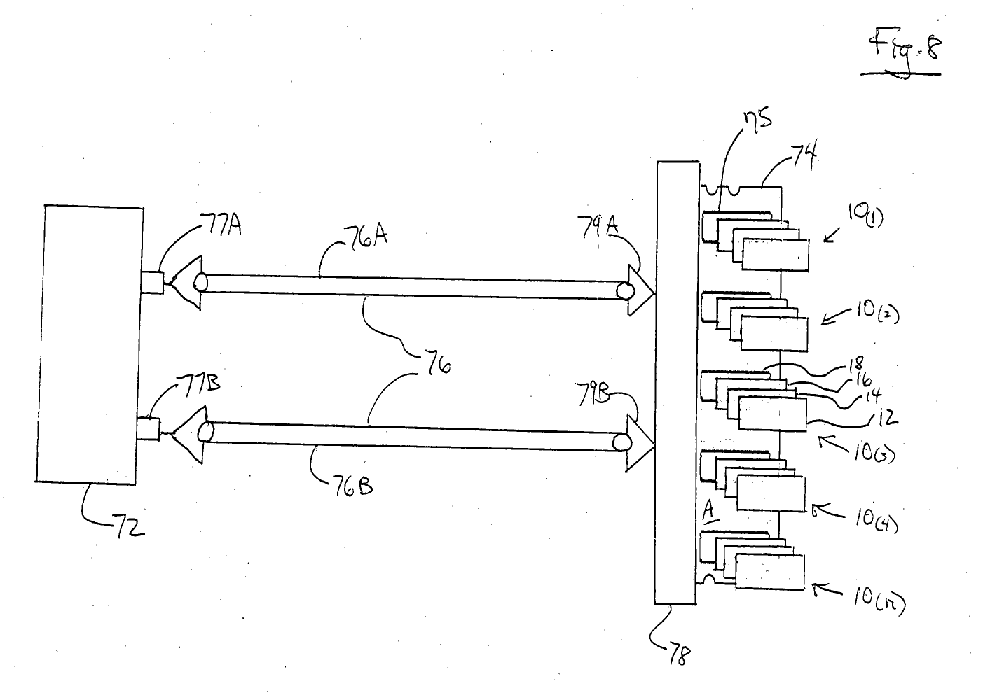

FIG. 8 is a depiction of a memory access system 70 in accordance with a preferred embodiment of the present invention. System 70 includes controller 72 lo which may be a memory controller, chip set, microprocessor, microcontroller or other memory control logic circuitry.

Memory expansion board 74 may be any memory expansion board such as, for example, the typical dual-in line memory module (DIMM) commonly found in computer systems. Depicted memory expansion board 74 is shown as being populated with modules 10₍₁₎, 10₍₂₎, 10₍₃₎, 10₍₄₎, to 10₍ₙ₎, each of which is preferably comprised from four integrated circuits. For clarity of exposition, memory expansion board 74 is shown in FIG. 8 as having five modules 10 on side A of expansion board 74, with one attached to each of the 5 IC sites 75. As is understood, a typical DIMM is populated on both of its sides.

It should be understood, however, that memory expansion boards 74 often exhibit a larger number of IC sites 75 (i.e., sockets, for example, or pad arrays) on a side, such as the nine IC sites 75 per side that are more typically found on a DIMM and that the present invention does not limit memory expansion board 74 to any particular format or number of IC sites 75 or modules 10.

In a preferred embodiment, memory expansion board 74 is connected to memory controller 72 by a transmission line 76 which has a controller end 77 and a memory end 79. In a preferred embodiment, transmission line 76 may be characterized as transmission line path 76A (data) and transmission line path 76B (command/address). Transmission line data path 76A and transmission line command/address path 76B each have a controller end 77A and 77B, respectively, and a memory end 79A and 79B, respectively. Controller ends 77A and 77B are connected to controller 72 and memory ends 79A and79B are connected to a memory interface site 78 and, therefore, are connected to memory expansion board 74. Memory interface site 78 may be a socket in some embodiments, while in other embodiments, direct wiring connection of memory expansion board 74 to memory end 79 of transmission line 76 may also be considered to provide the connection to memory interface site 78. In some embodiments, data path 76A and transmission line command/address path 76B can be characterized as a transmission line assemblage 76. There are other bus architectures to which the present invention may be adapted, as those of skill will recognize. The common attribute amongst the various types of memory expansion boards 74 that may be employed in the present invention is population with stacked memory modules each of which modules 10 is preferably constructed as disclosed in this application or the applications that have been incorporated by reference. It should also be noted that the invention may include use of modules 10 that are comprised from integrated circuits that include more than one integrated circuit die and may be leaded but leaded packages will present a higher profile and larger footprint.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A memory access system comprising:
a controller;
a memory site;
a memory signal transmission path, the memory signal transmission path having a first end and a second end with the first end being connected to the controller and the second end being connected to the memory site;
a memory expansion board connected to the memory site and the memory expansion board being populated with a plurality of modules, each of which modules is comprised of:
a first flex circuit having first and second conductive layers between which conductive layers is an intermediate layer, the first and second conductive layers being interior to first and second outer layers of the first flex circuit, the second conductive layer having upper and lower flex contacts, the upper flex contacts being accessible through second windows through the second outer layer and the lower flex contacts being accessible through first windows through the first outer layer, the first conductive layer and the intermediate layer, the lower flex contacts being further accessible through module contact windows through the second outer layer;
a second flex circuit having first and second conductive layers between which conductive layers is an intermediate layer, the first and second conductive layers being interior to first and second outer layers of the second flex circuit, the second conductive layer having upper and lower flex contacts, the upper flex contacts being accessible through second windows through the second outer layer and the lower flex contacts being accessible through first windows through the first outer layer and the first conductive layer and the intermediate layer, the lower flex contacts being further accessible through module contact windows through the second outer layer;
a first integrated circuit having first and second lateral sides and upper and lower major surfaces with contacts along the lower major surface, the contacts of the first integrated circuit connected to the lower flex contacts of the first and second flex circuits;
a second integrated circuit having first and second lateral sides and upper and lower major surfaces with contacts along the lower major surface, the contacts of the second integrated circuit connected to the upper flex contacts of the first and second flex circuits, the first and second flex circuits being disposed about the first and second lateral sides, respectively, of the first integrated circuit to place the upper flex contacts of the first and second flex circuits between the first and second integrated circuits; and
a set of module contacts.

2. The memory access system of claim 1 in which the memory signal transmission path is comprised of an address and command transmission path and a data transmission path.

3. The memory access system of claim 1 in which the memory expansion board is a DIMM.

4. The memory access system of claim 1 further comprising:
a third integrated circuit; and
a fourth integrated circuit.

5. The memory access system of claim 4 in which the first, second, third, and fourth integrated circuits in each of the plurality of modules are separately accessed.

6. A memory access system comprising:
a controller;
a memory site;
a memory signal transmission path, the memory signal transmission path having a first end and a second end with the first end being connected to the 1o controller and the second end being connected to the memory site;
a memory expansion board connected to the memory site and the memory expansion board being populated with a plurality of modules, each of which modules is comprised of:
flex circuitry having first and second conductive layers, the second conductive layer having upper and lower flex contacts;
a first integrated circuit having first and second lateral sides and upper and lower major surfaces with contacts along the lower major surface, the contacts of the first integrated circuit connected to the lower flex contacts of the flex circuitry;
a second integrated circuit having first and second lateral sides and upper and lower major surfaces with contacts along the lower major surface, the contacts of the second integrated circuit connected to the upper flex contacts of the flex circuitry, the flex circuitry being disposed to place the upper flex contacts of the flex circuitry between the first and second integrated circuits.

7. The memory access system of claim 6 in which the second conductive layer of the flex circuitry comprises at least one demarked voltage plane and a voltage set of the upper flex contacts and a voltage set of the lower flex contacts connect voltage conductive contacts of the first and second integrated circuits to one of the at least one voltage planes.

8. The memory access system of claim 6 in which each of the plurality of modules further comprises at least one form standard.

9. The memory access system of claim 6 further comprising:
a third integrated circuit; and
a fourth integrated circuit.

10. The memory access system of claim 9 in which the first, second, third, and fourth integrated circuits in each of the modules of the plurality of modules are separately accessed.

11. A memory access system comprising:
a controller;
a memory site;
a memory signal transmission path, the memory signal transmission path having a first end and a second end with the first end being connected to the controller and the second end being connected to the memory site;
a memory expansion board connected to the memory site and the memory expansion board being populated with a plurality of modules, each of which modules is comprised of:
first flex circuitry;
second flex circuitry;
third flex circuitry;
a first integrated circuit having first and second lateral sides and upper and lower major surfaces with contacts along the lower major surface, the contacts of the first integrated circuit connected to the first flex circuitry;
a second integrated circuit having first and second lateral sides and upper and lower major surfaces with contacts along the lower major surface, the contacts of the second integrated circuit connected to the second flex circuitry;
a third integrated circuit having first and second lateral sides and upper and lower major surfaces with contacts along the lower major surface, the contacts of the third integrated circuit connected to the third flex circuitry; and
a fourth integrated circuit having first and second lateral sides and upper and lower major surfaces with contacts along the lower major surface, the contacts of the fourth integrated circuit connected to the third flex circuitry, the first, second, third, and fourth integrated circuits being disposed in a stacked relationship.

12. The memory access system of claim 11 in which the first flex circuitry, the second flex circuitry, and the third flex circuitry each are comprised of two conductive layers.

13. The memory access system of claim 11 in which the first, second, third, and fourth integrated circuits in each of the plurality of modules are separately accessed.

14. A memory access system comprising:
a controller;
a memory site;
a memory signal transmission path, the memory signal transmission path having a first end and a second end with the first end being connected to the controller and the second end being connected to the memory site and there being no memory connected to the memory signal transmission path other than through the memory site;
a single memory expansion board connected to the memory site and the memory expansion board being populated with a plurality of modules, each of which modules is comprised of:
a first CSP;
a second CSP;
a third CSP;
a fourth CSP, all of which CSPs are in a stacked arrangement, one above the other.

15. The memory access system of claim 14 in which the memory expansion board is a DIMM populated with 18 modules.

16. The memory access system of claim 14 in which a first form standard is disposed between the, first and second CSPs and a second form standard is disposed between the second and third CSPs and a third form standard is disposed between the third and fourth CSPs

17. The memory access system of claim 14 in which the first, second, third, and fourth CSPs in each of the plurality of modules are separately accessed.

18. A memory access system comprising:
a controller;
a memory site;
a memory signal transmission path, the memory signal transmission path having a first end and a second end with the first end being connected to the controller and the second end being connected to the memory site;
a memory expansion board connected to the memory site and the memory expansion board being populated with a plurality of modules, each of which modules is comprised of:
a first CSP having an upper surface and a lower surface and a body with a height H1 that is the shortest distance from the upper surface to the lower surface of the first CSP, and along the lower surface there are plural first CSP low profile contacts, each of which plural first CSP low profile contacts extends no more than 7 mils from the surface of the first CSP;
a second CSP in stacked disposition with the first CSP, the second CSP having an upper surface and a lower surface and a body with a height H2 that is the shortest distance from the upper surface to the lower surface of the second CSP, and along the lower surface there are plural second CSP low profile contacts, each of which plural second CSP low profile contacts extends no more than 7 mils from the surface of the second CSP;
a first flex circuitry that connects the first CSP and the second CSP, a portion of which flex circuitry is disposed between the first and second CSPs.

19. The memory access system of claim 18 in which the plural first CSP low profile contacts and the plural second CSP low profile contacts are HT joints.

20. The memory access system of claim 18 in which plural module contacts are disposed along the first flex circuitry.

21. The memory access system of claim 18 in which the shortest distance from the lower surface of the second CSP to the upper surface of the first CSP that passes through one of the plural second CSP low profile contacts is less than 11 mils.

22. The memory access system of claim 18 in which the first flex circuitry is comprised of two flex circuits, each of which flex circuits has two conductive layers.

23. The memory access system of claim 18 in which the shortest distance from the lower surface of the second CSP to the upper surface of the first CSP that passes through one of the plural second CSP low profile contacts is no more than 9 mils.

24. The memory access system of claim 18 in which the first flex circuitry is comprised of two flex circuits, each of which flex circuits has one conductive layer.

25. The memory access system of claim 18 further comprising a form standard disposed above the upper surface of the first CSP.

26. The memory access system of claim 25 in which the shortest distance from the lower surface of the second CSP to the upper surface of the first CSP that passes through one of the plural second CSP low profile contacts is no more than 17 mils.

27. The memory access system of claim 18 further comprising:
a first form standard disposed above the upper surface of the first CSP; and
the first flex circuitry is comprised of two flex circuits, each of which flex circuits has two conductive layers at least one of which conductive layers has plural flex contacts and in which the shortest distance from the lower surface of the second CSP to the upper surface of the first CSP that passes through one of the plural second CSP low profile contacts is no more than 17 mils

28. The memory access system of claim 27 in which the plural first CSP low profile contacts and the plural second CSP low profile contacts are HT joints, selected ones of which HT joints are in contact with flex contacts of the first flex circuitry.

29. The memory access system of claim 18 further comprising:
a third CSP having an upper surface and a lower surface and a body with a height H3 that is the shortest distance from the upper surface to the lower surface, and along the lower surface there are plural third CSP low profile contacts, each of which plural third CSP low profile contacts extends no more than 7 mils from the surface of the third CSP;
a fourth CSP in stacked disposition with the third CSP, the fourth CSP having an upper surface and a lower surface and a body with a height H4 that is the shortest distance from the upper surface to the lower surface, and along the lower surface there are plural fourth CSP low profile contacts, each of which plural fourth CSP low profile contacts extends no more than 7 mils from the surface of the fourth CSP, the third CSP being disposed above the second CSP and the fourth CSP being disposed above the third CSP; and
a second flex circuitry connecting the second CSP and the third CSP; and
a third flex circuitry connecting the third CSP and the fourth CSP.

30. The memory access system of claim 29 in which the first, second, third, and fourth CSPs in each of the modules of the plurality of modules are separately accessed.

31. The memory access system of claim 29 in which the first CSP is disposed beneath the second CSP and the shortest distance from the upper surface of the fourth CSP to the lower surface of the first CSP that passes through at least one of the plural fourth CSP low profile contacts is less than HEIGHT where HEIGHT=45 mils+H1+H2+H3+H4.

32. The memory access system of claim 29 further comprising first, second and third form standards each respectively disposed above the upper surface of the first, second, and third CSPs.

33. The high-density circuit module of claim 32 in which the shortest distance from the upper surface of the fourth CSP to the lower surface of the first CSP that passes through at least one of the plural fourth CSP low profile contacts is less than HEIGHTFS where HEIGHTFS=65 mils+H1+H2+H3+H4.

34. The high-density circuit module of claim 18 further comprising:
a third CSP having an upper surface and a lower surface and a body with a height H3 that is the shortest distance from the upper surface to the lower surface, and along the lower surface there are plural third CSP low profile contacts, each of which plural third CSP low profile contacts extends no more than 7 mils from the surface of the third CSP;
a fourth CSP in stacked disposition with the third CSP, the fourth CSP having an upper surface and a lower surface and a body with a height H4 that is the shortest distance from the upper surface to the lower surface, and along the lower surface there are plural fourth CSP low profile contacts, each of which plural fourth CSP low profile contacts extends no more than 7 mils from the surface of the fourth CSP, the third CSP being disposed above the second CSP and the fourth CSP being disposed above the third CSP; and
a second flex circuitry connecting the second CSP and the third CSP, the second flex circuitry being comprised of two conductive layers at least one of which two conductive layers has plural flex contacts; and
a third flex circuitry connecting the third CSP and the fourth CSP, the second flex circuitry being comprised of two conductive layers at least one of which two conductive layers has plural flex contacts; and
second and third form standards respectively disposed above the second and third CSPs.

35. The memory access system of claim 34 in which at least one of the flex contacts has an orifice.

36. The memory access system of claim 34 in which the first, second, and third form standards are comprised of copper.

37. The memory access system of claim 34 in which the shortest distance from the lower surface of the fourth CSP to the upper surface of the first CSP that passes through one of the plural fourth CSP low profile contacts is less than HEIGHT4 where HEIGHT4=65 mils+H1+H2+H3+H4.

38. The memory access system of claim 34 in which the first, second, third, and fourth CSPs in each of the plurality of modules are separately accessed.

39. A memory access system comprising:
a controller;
a memory expansion board, the memory expansion board being populated with a plurality of modules, each of which modules comprising:
a first CSP;
a second CSP, the second CSP being disposed above the first CSP;
flex circuitry connecting the first CSP and the second CSP, the flex circuitry having plural flex contacts of which at least one has an orifice that has a median opening extent of DO; and
plural consolidated contacts, a selected one of which passes through the orifice and the selected one of the plural consolidated contacts having an inner flex portion and an outer flex portion delineated by the orifice, the selected one of the plural consolidated contacts providing a connection between the first CSP and the flex circuitry and the outer flex portion of the selected one of the plural consolidated contacts having a median lateral extent of DCC and DCC is larger than DO; and
a memory signal transmission path having a first end connected to the controller and a second end connected to the memory expansion board and there being no other memory connected to the transmission path other than that with which the memory expansion board is populated.

40. The memory access system of claim 39 further comprising in each of the plurality of modules with which the memory expansion board is populated:
a third CSP; and
a fourth CSP.

41. The memory access system of claim 40 in which the first, second, third, and fourth CSPs in each of the plurality of modules are accessed individually.
